(19) United States
(12) Patent Application Publication
(10) Pub. No.: US 2025/0331123 A1
(43) Pub. Date: Oct. 23, 2025

(54) COOLING SYSTEM FOR PROTECTIVE MOBILE DEVICE CASES

(71) Applicant: NLU Products, L.L.C., Lehi, UT (US)

(72) Inventors: Jordan MELVILLE, Lehi, UT (US); Ryan Hunter HOFSTRAND, Lehi, UT (US); Quinlan DRAPER, Lehi, UT (US)

(21) Appl. No.: 18/641,517

(22) Filed: Apr. 22, 2024

(51) Int. Cl. H05K 7/20; G06F 1/20; H04B 1/3888; H04M 1/04

(52) U.S. Cl. CPC H05K 7/20136; G06F 1/203; H04B 1/3888; H04M 1/04; H05K 7/2039

(57) ABSTRACT

A protective mobile device case can provide heat dissipation from a mobile device. The device case can include a sidewall perimeter member, a back plate member, a set of ventilation channels, and a cooling gel layer. The sidewall perimeter can be shaped to at least partially circumscribe a perimeter of the mobile device. The back plate can be associated with the sidewall perimeter and have an inward side facing the mobile device and an outward side facing an external environment. The ventilation channels can be oriented along the inward side and have vent outlets oriented adjacent the sidewall perimeter. The ventilation channels can vent to the external environment when the mobile device is within the device case. The cooling gel layer can be associated with the inward side and be configured to contact at least a portion of the ventilation channels and a back side of the mobile device.

### CROSS REFERENCE TO RELATED APPLICATIONS

None.

### BACKGROUND

Over the past several years mobile phones have become increasingly ubiquitous, while also providing increasing capabilities and performance. Along with increasing performance, additional power requirements are also demanded from the corresponding power supply of the mobile device. One factor which effects performance of these power supplies, i.e. batteries, is heat dissipation.

Currently, typical protective mobile device cases tend to provide moderate to excellent protection from physical damage due to impacts. However, these protective mobile device cases often have the unfortunate drawback of increasing insulation around the mobile device, and can also decrease thermal conduction and heat flow away from the battery and corresponding electronics within the mobile device. This can lead to an increase in operating temperature of the battery during use and charging. Increased operating temperatures also tend to decrease performance of the battery and mobile device, which can further reduce battery health and maximum battery capacity.

### SUMMARY

This disclosure relates to a cooling system for a protective mobile device case that provides heat dissipation from a mobile device power supply, such as a battery, during use. The protective mobile device case can include a sidewall perimeter member, a back plate member, a set of ventilation channels associated with the back plate member, and a cooling gel layer. The sidewall perimeter member can be shaped to at least partially circumscribe a perimeter of a mobile device. The back plate member can be associated with the sidewall perimeter member and have an inward side (i.e., facing the mobile device) and an outward side (i.e., facing a user's hand). The set of ventilation channels can be oriented along the inward side and can have vent outlets oriented adjacent the sidewall perimeter. The ventilation channels can vent to surrounding environment when the mobile device is placed within the protective mobile device case. The cooling gel layer can be associated with the inward side and in contact with at least a portion of the set of ventilation channels and can be configured to contact a back side of the mobile device.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1A illustrates a schematic exploded view of a protective mobile device case having a cooling layer and an optional magnetic array in accordance with one example.

FIG. 1B illustrates another view of the example protective mobile device case of FIG. 1A in an assembled condition.

FIG. 2 illustrates a partial side view of the protective mobile device case of FIG. 1A and a mobile device, in accordance with one example.

FIG. 3 illustrates a cross-sectional side view of a portion of an assembled example protective mobile device case adjacent a single ventilation channel, in accordance with another example.

FIG. 4 illustrates a cross-sectional view of another assembled protective mobile device case, in accordance with still another example.

FIG. 5 illustrates a cross-sectional view of another assembled protective mobile device case, in accordance with still another example.

These drawings are provided to illustrate various aspects of the invention and are not intended to be limiting of the scope in terms of dimensions, materials, configurations, arrangements or proportions unless otherwise limited by the claims.

### DETAILED DESCRIPTION

While these exemplary embodiments are described in sufficient detail to enable those skilled in the art to practice the invention, it should be understood that other embodiments may be realized and that various changes to the invention may be made without departing from the spirit and scope of the present invention. Thus, the following more detailed description of the embodiments of the present invention is not intended to limit the scope of the invention, as claimed, but is presented for purposes of illustration only and not limitation to describe the features and characteristics of the present invention, to set forth the best mode of operation of the invention, and to sufficiently enable one skilled in the art to practice the invention. Accordingly, the scope of the present invention is to be defined solely by the appended claims.

### Definitions

In describing and claiming the present invention, the following terminology will be used.

The singular forms “a,” “an,” and “the” include plural referents unless the context clearly dictates otherwise. Thus, for example, reference to “a channel” includes reference to one or more of such features, and reference to “the layer” refers to one or more of such structures.

As used herein with respect to an identified property or circumstance, “substantially” refers to a degree of deviation that is sufficiently small so as to not measurably detract from the identified property or circumstance. The exact degree of deviation allowable may in some cases depend on the specific context.

As used herein, “adjacent” refers to the proximity of two structures or elements. Particularly, elements that are identified as being “adjacent” may be either abutting or connected. Such elements may also be near or close to each other without necessarily contacting each other. The exact degree of proximity may in some cases depend on the specific context.

As used herein, the term “about” is used to provide flexibility and imprecision associated with a given term, metric or value. The degree of flexibility for a particular variable can be readily determined by one skilled in the art. However, unless otherwise enunciated, the term “about” generally connotes flexibility of less than 2%, and most often less than 1%, and in some cases less than 0.01%.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

As used herein, the term “at least one of” is intended to be synonymous with “one or more of.” For example, “at least one of A, B and C” explicitly includes only A, only B, only C, or combinations of each.

Numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of about 1 to about 4.5 should be interpreted to include not only the explicitly recited limits of 1 to about 4.5, but also to include individual numerals such as 2, 3, 4, and sub-ranges such as 1 to 3, 2 to 4, etc. The same principle applies to ranges reciting only one numerical value, such as “less than about 4.5,” which should be interpreted to include all of the above-recited values and ranges. Further, such an interpretation should apply regardless of the breadth of the range or the characteristic being described.

Any steps recited in any method or process claims may be executed in any order and are not limited to the order presented in the claims. Means-plus-function or step-plus-function limitations will only be employed where for a specific claim limitation all of the following conditions are present in that limitation: a) “means for” or “step for” is expressly recited; and b) a corresponding function is expressly recited. The structure, material or acts that support the means-plus function are expressly recited in the description herein. Accordingly, the scope of the invention should be determined solely by the appended claims and their legal equivalents, rather than by the descriptions and examples given herein.

### EXAMPLE EMBODIMENTS

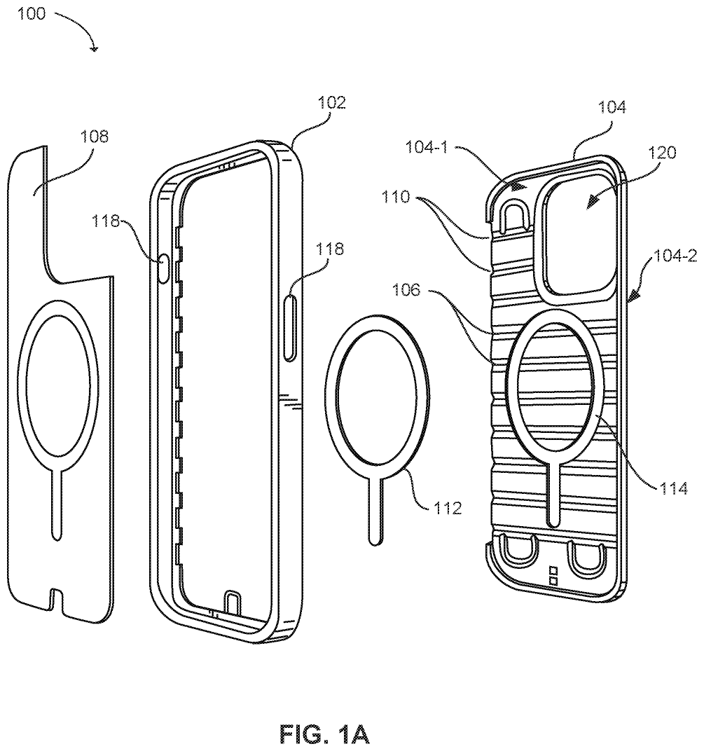

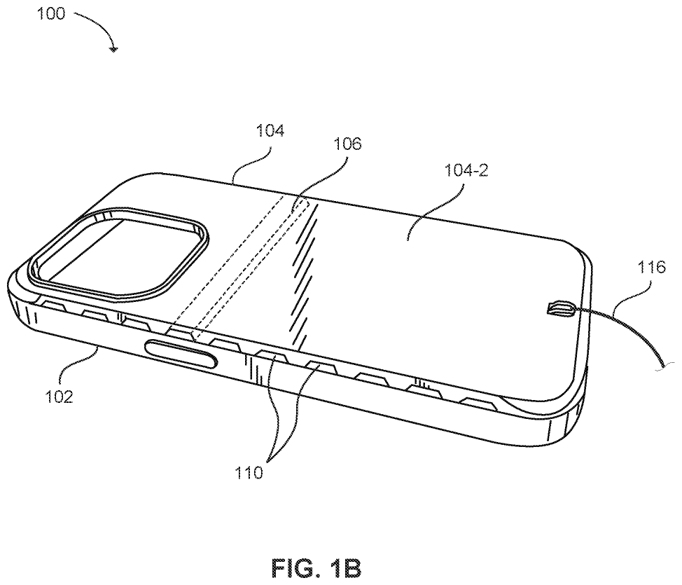

FIG. 1A illustrates an example protective mobile device case 100 that can provide heat dissipation from a mobile device battery during use. The protective mobile device case 100 (also referred to as the device case) can include a sidewall perimeter member 102, a back plate member 104, a set of ventilation channels 106 associated with the back plate member 104 (also referred to as the ventilation channels), and a cooling gel layer 108. The sidewall perimeter member 102 can be shaped to at least partially circumscribe a perimeter of a mobile device (not shown in FIG. 1A). The back plate member 104 can be associated with the sidewall perimeter member 102 and have an inward side (i.e., facing the mobile device) 104-1 and an outward side (i.e. facing a user's hand) 104-2. The set of ventilation channels 106 can be oriented along the inward side 104-1 and have vent outlets 110 oriented adjacent the sidewall perimeter member 102. The ventilation channels 106 can vent to the surrounding environment when the mobile device is placed within the protective mobile device case. The cooling gel layer 108 can be associated with the inward side 104-1 and can be in contact with at least a portion of the set of ventilation channels 106. The cooling gel layer 108 can also be configured to contact at least a portion of a back side of the mobile device (e.g., the non-screen side).

FIG. 1B illustrates an assembled perspective view of the protective mobile device case 100 showing the ventilation outlets 110 in accordance with an example of the present disclosure. The device case 100, as shown in FIG. 1B, also includes the sidewall perimeter member 102, the back plate member 104 (and the outward side 104-2), the ventilation channels 106, and an optional leash 116.

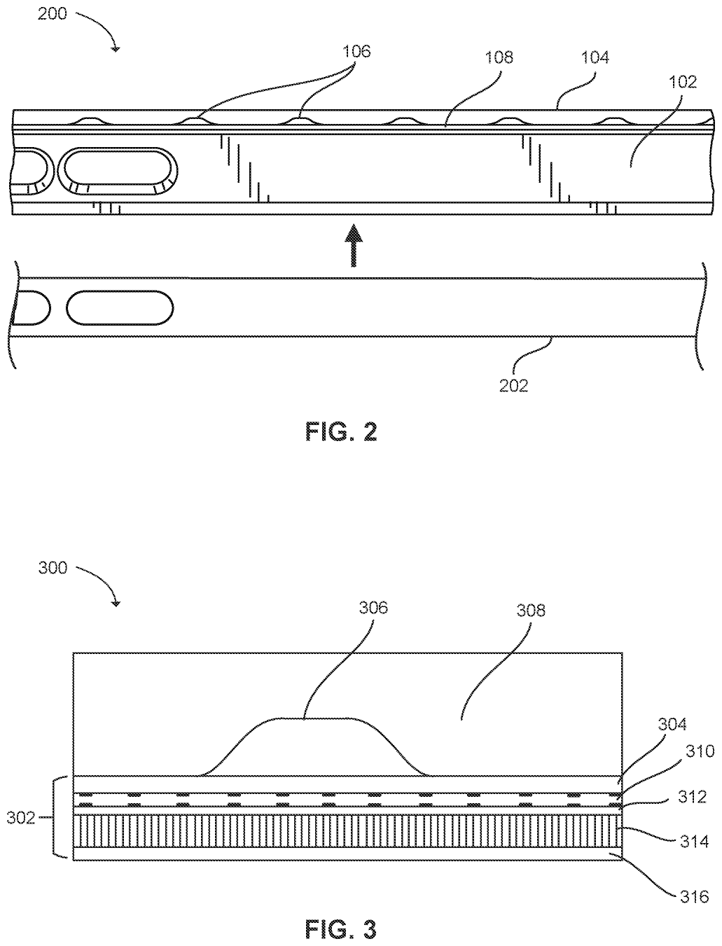

FIG. 2 illustrates a partial side view of an assembled implementation of the protective mobile device case 100 of FIGS. 1A and 1B (also referred to as the assembled device case 200). The back plate member 104, including the ventilation channels 106, is shown at the top of the example assembled device case 200. The cooling gel layer 108 is shown between the back plate member 104 and the sidewall perimeter member 102. The example assembled device case is configured to allow a mobile device 202 to fit into the assembled protective mobile case from the bottom the assembled device case 200 as shown in FIG. 2, such that the back side of the mobile device can contact the cooling gel layer 108.

Returning to FIGS. 1A and 1B, many mobile devices are now designed with inductive charging capability that allows charging of the device battery without the use of a physical charging cable. The presence of a protective device case can introduce an electrically insulating element of multiple layers which can reduce or otherwise inhibit transfer of charge from a charging station across the protective case to the device battery. Furthermore, some inductive charging stations use a magnetic element to improve position alignment of the device with the charger. Thus, in some example implementations, a magnetic element 112 can be embedded in the back plate member 104 in order to facilitate magnetic positioning of the mobile device with a magnetic coupling charger. The magnetic element 112 can include, for example, a magnetic loop array oriented within a recessed loop 114 within the inward side 104-1. For example, the magnetic element can include one or more permanent magnet elements oriented in a loop or other shape that does not interfere with inductive charge transfer across the back plate member 104 of the protective mobile device case 100. In some examples, the magnetic element 112 can be recessed into the back plate sufficient to avoid blocking the ventilation channels 106.

In some examples, the sidewall perimeter member 102 can completely circumscribe the perimeter of the mobile device, as illustrated in FIG. 1A-1B. This implementation can provide impact protection for the mobile device regardless of the angle and position of impact. However, in some examples (not shown), the sidewall perimeter member 102 can cover only portions of the perimeter of the mobile device. For example, the sidewall perimeter member 102 can include corner portions with one or more voids along one, two, three, or four straight side portions. Furthermore, as shown in FIG. 1A, the sidewall perimeter 102 can also have access openings 118 to allow for accessories, power ports, input/output ports, access to memory and SIM cards, speakers, power buttons, volume buttons, and so forth. These openings can optionally be covered with moveable dust and moisture protection hatches which can be opened and closed to protect the device from dust and moisture when not in use. In another alternative, when oriented over operable buttons, such openings can include an intermediate button which fits within and is retained within the openings and which allows operation of underlying buttons.

The protective mobile device case 100 can also include a device engagement mechanism (not shown in FIG. 1A-1B) which allows the case to remain secured with and/or around a mobile device. For example, the sidewall perimeter member 102 can include an inward facing lip which runs along at least a portion of the sidewall perimeter member 102, and which is adapted to retain the mobile device within the sidewall perimeter member 102. In this manner, the mobile device is retained via friction fit within the mobile device case 100 (i.e. no adhesives, latches, etc.). One example mechanism to allow insertion is providing a sidewall perimeter member 102 that is sufficiently flexible to allow insertion of the mobile device within the sidewall perimeter member 102 (i.e., the sidewall can be stretched to allow the mobile device to fit and then resiliently return to an original shape to secure the mobile device within the case). In one example, the sidewall perimeter member 102 can be formed of a thermoplastic polyurethane. In other examples, the sidewall perimeter member 102 can be formed of any suitable polymer such as polyurethane, polycarbonate, silicone, or the like.

In some examples, the back plate member 104 can be integrally formed with the sidewall perimeter member 102 as a single molded piece. In these examples, the back plate member 104 and the sidewall perimeter member 102 can be formed of a common material. In other examples, the back plate member 104 and the sidewall perimeter member 102 can be formed of two or more distinct materials which are molded contemporaneously to form a unitary piece. In some such cases, the separate materials can be allowed to slightly melt with one another to provide a non-separable fusing of the two materials. In other example cases, the two or more materials can be molded having an interlocking interface which also mechanically joins the pieces together. In some examples, the back plate member 104 is formed of a polycarbonate. As with the sidewall perimeter member 102, the back plate member 104 can be formed of any suitable polymer such as polyurethane, polycarbonate, silicone, or the like.

In some examples, the back plate member 104 and the sidewall perimeter member 102 can be formed as two separate pieces which are subsequently secured together. For example, the back plate member 104 can be engaged with the sidewall perimeter member 102 via a securing mechanism (not shown in FIG. 1A-1B). Non-limiting examples of suitable securing mechanisms can include at least one of a frictional interference fit, an adhesive, a tongue and groove mechanism, one or more detents, and a passive perimeter lip (e.g. a lip is oriented on the sides of the sidewall perimeter member 102, the back plate member 104 lays in the lip, and the mobile device physically pushes and holds the back plate member 104 in place against the lip).

As with the sidewall perimeter member 102, the back plate member 104 can include openings for various accessories. For example, the back plate can include a device camera window opening 120, as shown in FIG. 1B.

The ventilation channels 106 can be oriented and distributed so as to facilitate convective heat and air flow across the back plate member 104 and toward vent outlets 110. In one example, the ventilation channels 106 are embedded within the inward side 104-1 (e.g., formed as channels within the surface of the inward side 104-1). The ventilation channels 106 can be distributed across substantially an entirety of the inward side 104-1, or in select areas (e.g., areas correlated with higher temperatures during use). In one example, the ventilation channels 106 are oriented substantially parallel to one another and extend across the inward side 104-1 from side to side (e.g., left to right sides). The pattern of the set of ventilation channels 106 can vary considerably. However, in one example the set of ventilation channels 106 are spaced apart about 1 to 2 cm.

In another example, the vent outlets 110 can be oriented adjacent but separate from the sidewall perimeter member 102 and are oriented outwardly facing along sides of the mobile device case. In other words, facing along a device plane of the mobile device case, as opposed toward the back or front of the case. In yet another example, the vent outlets 110 are oriented within the sidewall perimeter member 102.

The cooling gel layer 108 can generally extend across areas where heat dissipation is desired. In some cases, the cooling gel layer 108 extends across at least 50% of the inward side, in other cases the cooling gel layer extends across at least 90% of the inward side, and in yet other cases the cooling gel layer extends across substantially all of the inward side. Similarly, the cooling gel layer can be in contact with substantially all of the plurality of ventilation channels 106. However, in some cases the cooling gel layer can be limited to contacting only a portion of the ventilation channels 106.

In some implementations, the cooling gel layer 108 can comprise a hydrogel.

Specifically, the hydrogel can have an equilibrium water content which is a function of at least one of temperature, humidity, and chemical composition of the hydrogel. In an example hydrogel, as the temperature of the hydrogel increases, absorbed water within the hydrogel is released into the surrounding environment (e.g., through evaporation). Released water vapor carries heat away with it, which results in a cooling effect within the hydrogel and thus allows for additional heat absorption from the ventilation channels and from the mobile device. As the water content within the hydrogel drops below an equilibrium value for a given temperature and humidity, water vapor from surrounding ambient air is absorbed by the hydrogel. Thus, the hydrogel acts as a self-renewing cooling mechanism. Various hydrogels can be used. As non-limiting examples, the hydrogel can be at least one of a polyacrylamide hydrogel, a silicone hydrogel, a polymethacrylate (polymethacrylic acid, polydiethylaminocthyl methacrylate, polydimethylaminocthyl methacrylate, siloxymethacrylate, etc), polysodium acrylate, and combinations thereof.

FIG. 3 illustrates a partial cross-sectional view of another assembled example protective mobile device case 300 showing an area just around one ventilation channel 306. In the example 300, a cooling gel layer 302 can include a dust film 304 facing a set of ventilation channels 306 of the back plate member 308. The cooling gel layer 302 can also include a lattice substrate 310, which can be adjacent the dust film 304 and adapted to provide structural support to the cooling gel layer 302. Further, the cooling gel layer 302 can also include an adhesive layer 312 that is adjacent the lattice substrate 310 and opposite the dust film 304. In some examples, the adhesive layer 312 can be a silicone adhesive. The cooling gel layer 302 can also include a hydrogel layer 314 that is adjacent the adhesive layer 312 opposite the lattice substrate 310 and a heat dissipating layer 316 facing (e.g., configured to be in contact with) a mobile device (not shown in FIG. 3). In one example, the heat dissipating layer can be a silicone layer. In some examples, the dust film 304 can extend across the cooling gel layer 302 (e.g., across substantially all of the cooling gel layer 302). In some cases, the dust film 304 covers the cooling gel layer 302 substantially only along areas in contact with the ventilation channels 306.

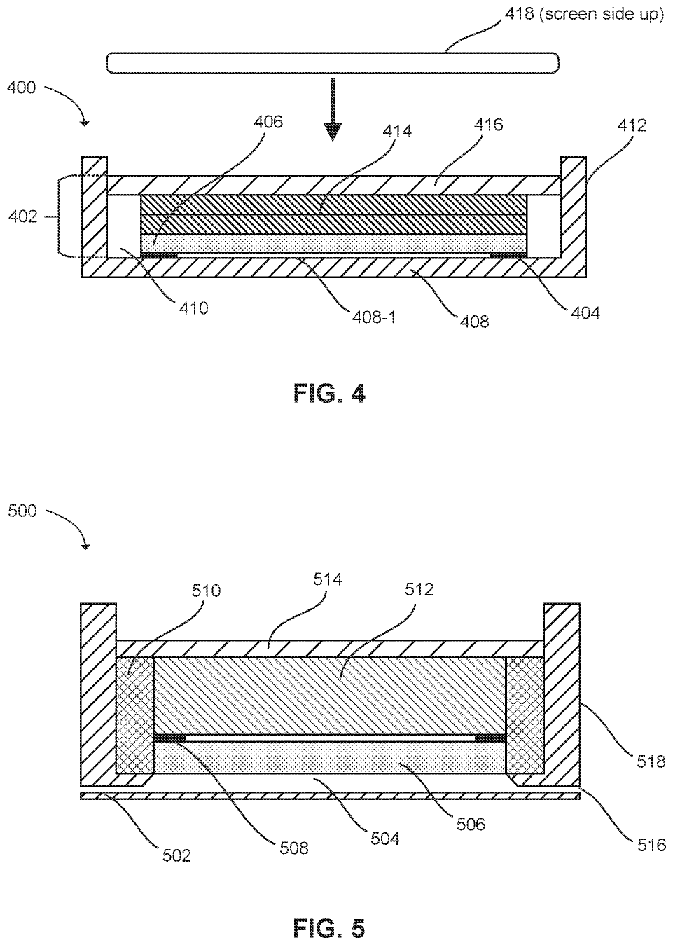

FIG. 4 illustrates a cross-sectional view of another assembled protective mobile device case 400 which is not to scale. In this example, a cooling gel layer 402 can include a mesh double-sided perimeter adhesive 404 oriented between a dust film 406 and an inward surface 408-1 of a back plate member 408 to secure the cooling gel layer 402 to the back plate member 408. In some cases, a double-sided foam adhesive layer 410 can be oriented to secure the cooling gel layer 402 to both the backplate member 408 and a side wall perimeter member 412. The cooling gel layer can also include one or both of a hydrogel cooling gel layer 414 and a silicone heat-dissipation layer 416 facing (e.g., configured to be in contact with) a mobile device 418.

FIG. 5 illustrates a cross-sectional view of still another assembled protective mobile device case 500. The example 500 includes a backplate member 502, ventilation channels 504, a dust film 506, a lattice substrate 508, a silicone adhesive 510, a silicone-based hydrogel core layer 512, and a heat-dissipation layer 514. The ventilation channels 504 include vent outlets 516 oriented to exit from the sides of the sidewall perimeter member.

In this example, the heat-dissipation layer 514 (e.g., a heat-dissipating silicone layer) is configured to be adjacent a back side of the mobile device (not shown in FIG. 5). The hydrogel core layer 512 is adjacent the heat-dissipation layer 514 (opposite the mobile device). In some example implementations, the silicone adhesive 510 can be used along a perimeter of the assembly to secure one or more layers to one or both of a sidewall perimeter member 518 and the back plate member 502. The lattice substrate 508 can be oriented around the perimeter to contact the dust film 506. The ventilation channels 504 can be adjacent to, and in contact with, the dust film 506.

The back plate member 502, and the other layers of FIG. 5 are shown as being substantially planar (e.g., coplanar with a device plane of the mobile device corresponding to a viewscreen of the mobile device). However, in other implementations, one or more of the components illustrated in FIG. 5 could be non-planar (e.g. concave, wavy, etc). Further, one or more of these layers can include surface texturing. For example, an outer surface of the back plate member can include surface texturing in order to provide grip or for specific aesthetic appearance.

Further, while FIG. 1A through FIG. 5 describe several examples, the different examples can be understood as depicting various aspects of a cooling system for a protective mobile device case, which can be combined in full or in part. For example, some or all of the back plate members 104, 308, 408, and 502 can be realized as the same back plate member. Similarly, the sidewall perimeter members, the cooling gel layers, and the other components described in the various figures can each be realized as the corresponding components in the other figures.

### Example 1

Charging times for the protective mobile device case illustrated generally by FIG. 1A and FIG. 1B was tested and compared to both a mobile device without a device case and a mobile device with other cooling designs for mobile device cases using an iPHONE 13 PRO at 0% battery charge, and an APPLE 20W MAGSAFE charger. Table 1 shows results of these tests. The device case of FIGS. 1A and 1B is labeled “Rivet with cooling gel and holes” (the other cases are: “Regular rivet (no holes or cooling tech)”; “Rivet with cooling gel”; and “Rivet with Thermoline”).

TABLE 1

| | | | | | Full |
|---|---|---|---|---|---|
| | Battery level | | | | charge |
| Test object | 30 min | 1 hour | 1.5 hours | 2 hour | time |
| Regular rivet | 37% | 61% | 83% | 98% | 2 hr 02 min |
| (no holes of | | | | | |
| cooling tech) | | | | | |
| Rivet with | 43% | 76% | 94% | 100% | 1 hr 46 min |
| cooling gel | | | | | |
| Rivet with | 43% | 75% | 94% | 100% | 1 hr 49 min |
| Thermoline | | | | | |
| Rivet with | 32% | 65% | 89% | 100% | 1 hr 55 min |
| cooling gel | | | | | |
| and holes | | | | | |
| Phone without | 36% | 67% | 89% | 100% | 1 hr 51 min |
| case | | | | | |

Table 1 shows a modest increase in charging time of 6% (122 total minutes for “Regular Rivet” and 115 total minutes for “Rivet with Cooling Gel”). Similarly, Table 1 shows a modest increase of 3.6% (111 total minutes for “Phone without case” and 115 total minutes for “Rivet with Cooling Gel and holes”).

### Example 2

Battery life at different ambient temperatures was also tested by starting with a 100% battery level and depleting the battery by recording a 4 k 30 fps video with flash and screen brightness at 100%. Tables 2-4 show the results of these tests.

TABLE 2
Testing Environment: −12° C.

| | Battery level | | | |
|---|---|---|---|---|
| Test object | 30 min | 1 hour | 1.5 hours | 2 hour |
| Regular rivet | 87% | 64% | 38% | 10% |
| (no holes or | | | | |
| cooling tech) | | | | |
| Rivet with | 84% | 60% | 26% | 10% |
| cooling gel | | | | |
| Rivet with | 83% | 57% | 29% | 5% |
| Thermoline | | | | |
| Rivet with cooling | 86% | 63% | 37% | 13% |
| gel and holes | | | | |
| Phone without case | 84% | 59% | 33% | 5% |

TABLE 3
Testing Environment: 22° C.

| | Battery level | | | |
|---|---|---|---|---|
| Test object | 30 min | 1 hour | 1.5 hours | 2 hour |
| Regular rivet (no holes or | 88% | 72% | 55% | 35% |
| cooling tech) | | | | |
| Rivet with cooling gel | 89% | 71% | 53% | 38% |
| Rivet with Thermoline | 86% | 68% | 51% | 33% |
| Rivet with cooling gel and | 89% | 70% | 58% | 41% |
| holes | | | | |
| Phone without case | 89% | 69% | 56% | 38% |

TABLE 4
Testing Environment: 38° C.

| | Battery level | | | |
|---|---|---|---|---|
| Test object | 30 min | 1 hour | 1.5 hours | 2 hour |
| Regular rivet (no holes of | 94% | 82% | 71% | 59% |
| cooling tech) | | | | |
| Rivet with cooling gel | 88% | 80% | 68% | 53% |
| Rivet with Thermoline | 93% | 81% | 69% | 52% |
| Rivet with cooling gel and | 92% | 79% | 67% | 54% |
| holes | | | | |
| Phone without case | 87% | 70% | 53% | 35% |

*The flash cannot be turned on at −38° C.

These results show that the testing performed with the cooling gel and ventilation holes. For example, Table 3 shows results at approximately room temperature (22° C.). The case illustrated generally by FIG. 1A and FIG. 1B (referred to as “the subject case”) (“Rivet with cooling gel and holes”) has, at the 2 hr mark, an 18% positive difference when compared to regular (non-cooling) case “Regular rivet” (41% battery left vs. 35%). Additionally, in other ambient conditions (Table 2 at −12° C. and Table 4 at 38° C.), the subject case has insulating properties when compared to a device with no case at all. The data show performance at lower temperature (Table 2:47.6% positive when compared to “Phone without case” and 26% better than “Regular Rivet”).

Reference was made to the examples illustrated in the drawings and specific language was used herein to describe the same. It will nevertheless be understood that no limitation of the scope of the technology is thereby intended. Alterations and further modifications of the features illustrated herein and additional applications of the examples as illustrated herein are to be considered within the scope of the description. Furthermore, the described features, structures, or characteristics may be combined in any suitable manner in one or more examples. In the preceding description, numerous specific details were provided, such as examples of various configurations to provide a thorough understanding of examples of the described technology. It will be recognized, however, that the technology may be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements may be devised without departing from the spirit and scope of the described technology.

What is claimed is:

1. A protective mobile device case, comprising:
a sidewall perimeter member shaped to at least partially circumscribe a perimeter of a mobile device;
a back plate member associated with the sidewall perimeter member and having an inward side and an outward side;
a set of ventilation channels oriented along the inward side and having vent outlets oriented adjacent the sidewall perimeter member and which vent to surrounding environment when the mobile device is placed within the protective mobile device case; and
a cooling gel layer associated with the inward side and in contact with at least a portion of the set of ventilation channels and configured to contact at least a portion of a back side of the mobile device.

2. The mobile device case of claim 1, wherein the sidewall perimeter member completely circumscribes the perimeter of the mobile device.

3. The mobile device case of claim 1, wherein the sidewall perimeter member includes an inward facing lip which runs along at least a portion of the sidewall perimeter member and is adapted to retain the mobile device within the sidewall perimeter.

4. The mobile device case of claim 3, wherein the sidewall perimeter member is sufficiently flexible to allow insertion of the mobile device within the sidewall perimeter member.

5. The mobile device case of claim 1, wherein the back plate member is integrally formed with the sidewall perimeter member as a single molded piece.

6. The mobile device case of claim 1, wherein the back plate member is engaged with the sidewall perimeter member via a securing mechanism.

7. The mobile device case of claim 6, wherein the securing mechanism is at least one of a frictional interference fit, an adhesive, a tongue and groove mechanism, one or more detents, and a passive perimeter lip.

8. The mobile device case of claim 1, wherein the ventilation channels are embedded within the inward side.

9. The mobile device case of claim 1, wherein the ventilation channels are distributed across substantially an entirety of the inward side.

10. The mobile device case of claim 1, wherein the set of ventilation channels are oriented substantially parallel to one another and from side to side.

11. The mobile device case of claim 10, wherein the vent outlets are oriented adjacent but separate from the sidewall perimeter member and are oriented outwardly facing along sides of the mobile device case.

12. The mobile device case of claim 10, wherein the vent outlets are oriented within the sidewall perimeter member.

13. The mobile device case of claim 10, wherein the set of ventilation channels are spaced apart 1 to 2 cm.

14. The mobile device case of claim 1, wherein the cooling gel layer extends across at least 50% of the inward side.

15. The mobile device case of claim 1, wherein the cooling gel layer extends across at least 90% of the inward side.

16. The mobile device case of claim 1, wherein the cooling gel layer extends across substantially all of the inward side.

17. The mobile device case of claim 1, wherein the cooling gel layer is in contact with substantially all of the plurality of ventilation channels.

18. The mobile device case of claim 1, wherein the cooling gel layer includes a hydrogel.

19. The mobile device case of claim 18, wherein the hydrogel is at least one of a polyacrylamide hydrogel, a silicone hydrogel, a polymethacrylate hydrogel, and a polysodium acrylate hydrogel.

20. The mobile device case of claim 1, wherein the cooling gel layer comprises:
a dust film facing the set of ventilation channels;
a lattice substrate adjacent the dust film and adapted to provide structural support to the cooling gel layer;
an adhesive layer adjacent the lattice substrate and opposite the dust film;
a hydrogel layer adjacent the adhesive layer opposite the lattice substrate; and
a heat dissipating silicone layer facing the mobile device.

21. The mobile device case of claim 20, wherein the dust film extends across the cooling gel layer.

22. The mobile device case of claim 20, wherein the cooling gel layer includes a perimeter adhesive oriented between the dust film and the inward surface to secure the cooling gel layer to the back plate member.

23. The mobile device case of claim 1, wherein each of the back plate member, set of ventilation channels, and cooling gel layer are substantially planar.
